(19) United States
(12) Patent Application Publication
(10) Pub. No.: US 2009/0267164 A1
(43) Pub. Date: Oct. 29, 2009

(54) METHOD OF MANUFACTURING A SEMICONDUCTOR SENSOR DEVICE AND SEMICONDUCTOR SENSOR DEVICE

(75) Inventors: Olaf Wunnicke, Eindhoven (NL); Erik Petrus Antonius Maria Bakkers, Eindhoven (NL); Aarnoud Laurens Roest, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/438,561

(22) PCT Filed: Aug. 21, 2007
(86) PCT No.: PCT/IB2007/053328

§ 371 Date: Feb. 24, 2009

(30) Foreign Application Priority Data
Aug. 24, 2006 (EP) 06119487.4

(51) Int. Cl. H01L 29/66; H01L 21/302

(52) U.S. Cl. 257/414; 438/49; 977/762; 438/694; 257/E29.166; 257/E21.214; 438/691

(57) ABSTRACT

The invention relates to a method of manufacturing a semiconductor sensor device (10) for sensing a substance comprising a plurality of mutually parallel mesa-shaped semiconductor regions (1) which are formed on a surface of a semiconductor body (11) and which are connected at a first end to a first electrically conducting connection region (2) and at a second end to a second electrically conducting connection region (3) while a gas or a liquid comprising a substance to be sensed can flow between the mesa-shaped semiconductor regions (1) and the substance to be sensed can influence the electrical properties of the plurality of the mesa-shaped semiconductor regions (1), wherein at the surface of the semiconductor body (11) the first connection region (2) is formed and connected thereto with the first end the plurality of mesa-shaped semiconductor regions (1) is formed, and subsequently the second connection region (3) is formed connected to the plurality of mesa-shaped semiconductor regions (1) at their second end. According to the invention after formation of the plurality of mesa-shaped semiconductor regions (1) the free space between these regions (1) is filled with a fill material (4) that can be selectively removed with respect to the material of the plurality of mesa-shaped semiconductor regions (1) and of other bordering parts of the semiconductor sensor device (10), subsequently a conducting layer (30) is deposited over the resulting structure from which the second connection region (3) is formed whereinafter the fill material (4) is removed by selective removed by which the space between the plurality of mesa-shaped semiconductor regions (1) is made free again. In this way sensor devices (10) are manufacturing with a method that is easily applied on an industrial scale and results in a high yield.

### FIELD OF THE INVENTION

The invention relates to a method of manufacturing a semiconductor sensor device for sensing a substance comprising a plurality of mutually parallel mesa-shaped semiconductor regions which are formed on a surface of a semiconductor body and which are connected at a first end to a first electrically conducting connection region and at a second end to a second electrically conducting connection region while a fluid (=a liquid or a gas) comprising a substance to be sensed can flow between the mesa-shaped semiconductor regions and the substance to be sensed can influence the electrical properties of the plurality of the mesa-shaped semiconductor regions, wherein at the surface of the semiconductor body the first connection region is formed and connected thereto with the first end the plurality of mesa-shaped semiconductor regions is formed, and subsequently the second connection region is formed connected to the plurality of mesa-shaped semiconductor regions at their second end. The invention also relates to a semiconductor sensor device.

### BACKGROUND OF THE INVENTION

Such a method is very suitable for making sensor devices for detecting chemical and/or biochemical substances. In the latter case it can e.g. be used for detecting antigen/antibody bindings, biomolecules and others with a high sensitivity and reproducibility, and thus it can be used advantageously in gene analysis, disease diagnostics and the like. Moreover, the detection of simpler molecules like chemical substances that are volatile or dissolved in a liquid is also possible, e.g. by introduction by the substance of a charge into a nano-wire of which the conductivity is thus changed. Here with a nano wire a body is intended having at least one lateral dimension between 1 and 100 nm and more in particular between 10 and 50 nm. Preferably a nano-wire has dimensions in two lateral directions that are in the said ranges. The use of a plurality of nano-wires for the mesa-shaped semiconductor region enables the manufacture of sensors with a very high sensitivity. It is further noted here that contacting extremely small dimensions in semiconductors is a challenging technique in semiconductor processing. However, although the mesa-shaped semiconductor region is intended to comprise in particular a nano wire, the invention is also applicable to other mesa shaped semiconductor regions that have other dimensions. Mesa-shaped of a region means that the region forms a protrusion on the surface of the semiconductor body.

A method as mentioned in the opening paragraph is known from the PCT (=Patent Cooperation Treaty) patent application that has been published under number WO 2004/109815 on Dec. 16, 2004. In this document, for obtaining a sensor device, a number of mesa shaped semiconductor regions comprising single crystal nano wires are provided on a substrate. Various materials like zinc oxide, titanium oxide, silicon and III-V semiconductor materials are mentioned as the material of which the nano-wires are made. After the nano wire growth, a metal like Gold is selectively deposited on the upper surface of the nano-wires. In this way, a Schottky contact or an ohmic contact is made to the upper surface of the nano-wire. The metallized upper surface of a nano wire is subsequently covered with e.g. a fabric comprising a number of conducting platelets. For more detail on the structure and application of a sensor device as chemical or biochemical sensor see also PCT (=Patent Cooperation Treaty) patent application that has been published under number WO 2005/054869 on Jun. 15, 2005. In FIG. 2a an Au/Ti ohmic electrode was formed such that it forms a horizontal plate on the tip portions of the ZnO nanorods by an evaporation technique and heated to about 300° C. for 1 minute, to obtain a biosensor comprising ZnO nanorods vertically disposed on the substrate.

A drawback of such a method is that it is less suitable for mass production of semiconductor devices comprising a sensor. In addition, the nano-wires are easily damaged in mounting conducting platelets on top of the nano-wires. This reduces the yield.

### DESCRIPTION OF THE INVENTION

It is therefore an object of the present invention to avoid the above drawbacks and to provide a method, which is suitable for large scale manufacturing of semiconductor devices comprising a sensor with a plurality of mesa-shaped semiconductor regions, in particular nano-wires, and resulting in a high yield.

To achieve this, a method of the type described in the opening paragraph is characterized in that after formation of the plurality of mesa-shaped semiconductor regions the free space between these regions is filled with a fill material that can be selectively removed with respect to the material of the plurality of mesa-shaped semiconductor regions and of other bordering parts of the semiconductor sensor device, subsequently a conducting layer is deposited over the resulting structure from which the second connection region is formed whereinafter the fill material is removed in a selective manner by which the space between the plurality of mesa-shaped semiconductor region is made free again. Since the mesa-shaped semiconductor regions are embedded in a fill material, they are protected against damaging during the subsequent formation of a contact to the regions. Moreover, since the contact can be formed on a substantially flat surface, many industrial techniques can be used for forming the contact by deposition of a conducting layer, e.g. by vapor deposition, sputtering etc. At the beginning of the deposition there is, thanks to the presence of the fill material, no danger that the contact material will get between the mesa regions. At a later stage this is prevented by the thickness and stiffness of the deposited conducting layer. Thus, there is no need for use of a platelet in contact formation, nor of a selective deposition of any metal. If a selective deposition nevertheless is desired, the choice of materials and/or processes appears to be larger since the properties of the fill material offers some degree of freedom in this respect. Finally, the fill material can be removed completely in a simple manner e.g. by a selective etching process. Thus, the process according to the present invention is very suitable for a large-scale industrial manufacturing process and the resulting sensor devices are obtainable with high yield.

A preferred embodiment is characterized in that before the conducting layer is deposited, an upper part of the fill material is removed by selective etching by which an upper part of the plurality of mesa-shaped semiconducting regions is made free. In this way, the upper contact metallization can be interdigited with respect to the mesa regions or nano-wires. This contributes to protection of the wires against damaging forces. Moreover, the contact resistance at the upper side of the mesa can be reduced.

In a favorable embodiment the fill material is removed almost completely and the space between the plurality of mesa-shaped semiconductor regions is filled with a further fill material different from the fill material. In this way the foot of the mesas or nano-wires can be embedded in an enforcing layer. Said layer may be conducting or insulating. The latter being preferred if the mesas or nano-wires are formed on a (semi) conducting substrate and if a conducting medium is to be usable for the fluid carrying the compound or substance to be detected by the sensor device. The further fill material now functions as the fill material as discussed before. Thus, it should again be possible to selectively etch the further fill material and this also with respect to the fill material on which it is deposited. Again, before the conducting layer is deposited, an upper part of the further fill material is removed by etching by which an upper part of the plurality of mesa-shaped semiconductor regions is made free. This again enables the interdigited structure of the upper contact.

Preferably for the material of the fill material or the further fill material an insulating material is selected. Apart from the advantage mentioned before, these materials may be easily deposited and etched. Moreover, they do not interfere with current paths if they are not completely removed. Suitable materials are (irrespective of the order of use) silicon dioxide and silicon nitride which can be etched selectively e.g. by a buffered solution of hydrogen fluoride and hot phosphoric acid.

In a preferred embodiment of the fill material or the further fill material a polymer is used which is deposited by spin coating. This means that the (further) fill material is deposited in a cheap and fast manner.

In another modification the nano-wires are completely buried with a layer of the fill material, e.g. by a CVD process, followed by a CMP (=Chemical Mechanical Polishing) step by which the upper surfaces of the nano-wires are made free.

Preferably of the material of the fill material or the further fill material is selectively etched by wet etching. Although dry etching is feasible, wet etching offers the advantage that etching between a “wood” of mesas or nano-wires is simple and easy since such an etchant easily underetches.

For the final complete removal of the fill material, dry etching may in particular be used in case an organic substance as a fill material, using oxygen or another reactive component. In such cases, e.g. when a material like PMMA (=Poly Methyl Meta Acrylate) is used, also a thermal treatment may be considered for complete removal of the fill material. In these variations capillary forces that may damage the nano-wires are avoided.

In view of prevention of damaging of the mesas or nano-wires, a method according to the invention is preferable performed in such a manner that after wet etching of fill material or the further fill material, the capillary forces in the space between the plurality of mesa-shaped semiconducting regions in a subsequent drying step are reduced. The capillary forces during drying can be reduced by introducing between the etching and drying step a washing step using a liquid with a low surface tension. Such a liquid may be e.g. on an alcohol basis. In another attractive modification the capillary forces during drying are reduced by using supercritical cabondioxide drying.

Preferably, for the plurality of mesa-shaped semiconductor regions a nano-wire is chosen. Such nano-wires can easily be formed by, e.g. a VLS (=Vapor Liquid Solid) growth technique with very large numbers on a relatively small area. The distance between neighboring nano-wires may be typically selected between 0.1 and 10 μm, preferably around 1 μm, while their length is e.g. between 1 and 10 μm. In this way a sensor is obtainable with e.g. about 10⁶ nano-wires on a square contact area of 1 mm×1 mm, implying that the sensitivity is increased by the same factor compared to a sensor comprising one single nano-wire.

The nano-wires are preferably arranged such that a medium carrying the substance to be detected has to meander through the wood of nano-wires. The length direction of said wood can be selected to be smaller than the width. In this way, the medium passing through the sensor may face a lower flow resistance. Preferably, the nano-wires are of the normally off type or form part of a device with such a characteristic, such as a FET (=Field Effect Transistor). The substances to be detected will change the conductivity e.g. by introduction of a charge into the nano-wire after they are absorbed on the surface thereof. Due to the large surface-to-volume ratio of the nano-wire, a very high signal to noise ratio is obtainable in this way. However, other ways of detection are possible, e.g. the substance to be detected may form on the surface of the nano-wire which is (semi) insulating or semiconducting, a conducting layer.

The invention comprises a semiconductor sensor device obtained by a method according to the invention. The latter device may be formed on or attached to a (structured) further substrate. The construction of the latter or of the combined device being such that a tube carrying the medium/fluid with the substance/compound to be detected can be easily connected to the device. The manufacture of such a construction can be relatively easy be integrated with a method according to the invention.

Finally the invention comprises a semiconductor sensor device for sensing a substance comprising a plurality of mutually parallel mesa-shaped semiconductor regions which are formed on a surface of a semiconductor body and which are connected at a first end to a first electrically conducting connection region and at a second end to a second electrically conducting connection region while a fluid comprising a substance to be sensed can flow between the mesa-shaped semiconductor regions and the substance to be sensed can influence the electrical properties of the plurality of the mesa-shaped semiconductor regions, wherein at the surface of the semiconductor body the first connection region is formed and connected thereto with the first end the plurality of mesa-shaped semiconductor regions is formed, and the second connection region is formed connected to the plurality of mesa-shaped semiconductor regions at their second end and to part of the sidewalls of the plurality of mesa-shaped semiconductor regions. When the second connection region makes electrical contact to part of the sidewalls of the plurality of mesa-shaped semiconductor regions, the contact area is much larger than when only the second top ends are contacted. The larger contact area is beneficial to lower the contact resistance (inversely proportional to the contact area) and reduces spreading in contact resistance. Because biosensors have to be very sensitive, it is very important to have good ohmic behavior of the contacts with a very small spreading in contact resistance values. The larger contact area improves the mechanical stability of the plurality of mesa-shaped semiconductor regions.

These and other aspects of the invention will be apparent from and elucidated with reference to the embodiments described hereinafter, to be read in conjunction with the drawings.

### BRIEF DESCRIPTION OF THE DRAWINGS

FIGS. 1 through 4 are sectional views of a semiconductor sensor device at various stages in its manufacture by means of a method in accordance with the invention, and

FIG. 5 is a sectional view of another semiconductor sensor device at a relevant stage in its manufacture by means of another method in accordance with the invention.

The Figures are diagrammatic and not drawn to scale, the dimensions in the thickness direction being particularly exaggerated for greater clarity. Corresponding parts are generally given the same reference numerals and the same hatching in the various Figures.

### DETAILED DESCRIPTION OF THE EMBODIMENTS

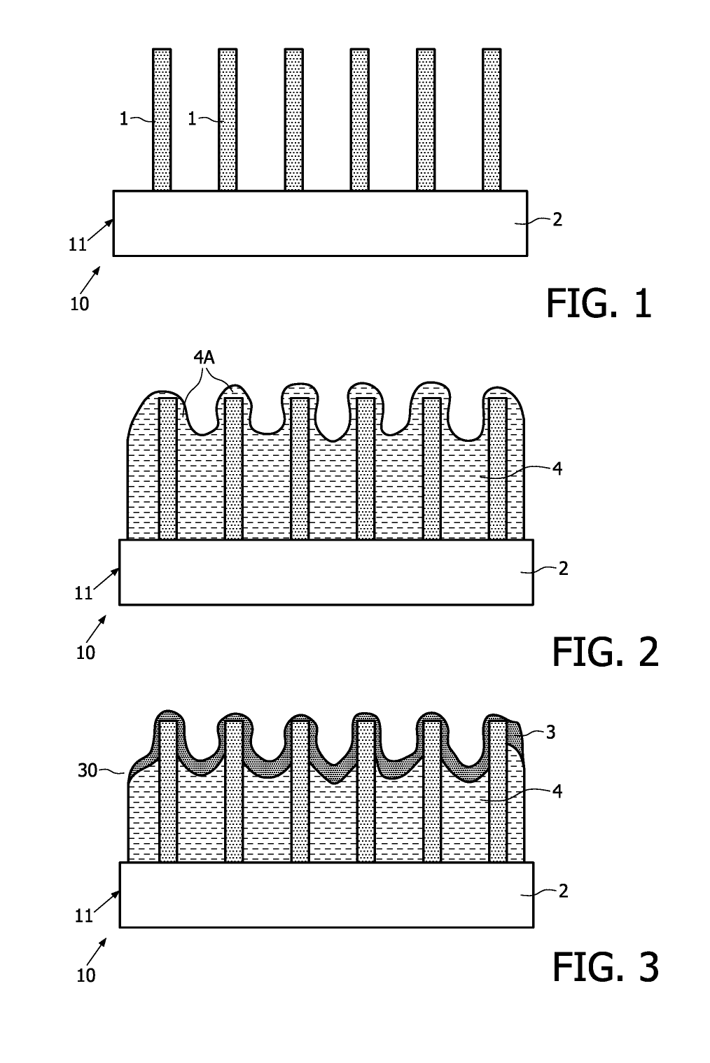

FIGS. 1 through 4 are sectional views of a semiconductor sensor device at various stages in its manufacture by means of a method in accordance with the invention. The semiconductor sensor device 10 to be manufactured may contain already at the stage in advance of FIG. 1 various elements or components in so far as desirable. Such elements or components are not shown in the drawing.

In a first relevant step of the manufacture of the device 10 (see FIG. 1) a silicon substrate 2 forming a silicon semiconductor body 11, is provided with a mesa-shaped semiconductor region 1, here a plurality of nano wires 1 comprising silicon. The regions 1 may be weakly p-doped while an upper part and lower part is n-type doped. The surface of the regions 1 may be covered by a thin oxide layer, e.g. formed by oxidation. In this way, a region one may function as a normally off type npn FET while a substance to be detected may introduce a conducting n-type channel into region 1 after having been absorbed on the surface of region 1. The wires 1 can be formed e.g. by photolithography and etching of a uniformly deposited layer but also by a selective deposition technique as described in e.g. “Vapor-liquid-solid mechanism of single crystal growth” by R. S. Wagner and W. C. Ellis that has been published in Applied Physics Letters, vol. 4, no. 5, 1 march 1964, pp 89-90. In this example the height of the pillar 1 is about 500 nm and its diameter is about 50 nm.

Subsequently (see FIG. 2) a relatively thick layer 4 comprising an insulating material. The layer 4 may comprise a polymer (e.g. a (photo) resist) deposited by spin coating or a material like silicon dioxide which may be conformal deposited using CVD (=Chemical Vapor Deposition) and TEOS (=Tetra Ethyl Ortho Silicate) as source material. Also a non-conformal deposition of silicon dioxide using a HDP (=High Density Plasma) deposition process is possible. In this example a resist layer 4 is deposited using spin coating. An upper part 4A of said layer is then removed by an etching step. In a modification, the nano-wires 1 may be completely buried by the fill-material and CMP (=Chemical Mechanical Polishing) is used before the etching step by which the upper regions 4A of the fill material are removed by which the upper parts of the nano-wires 1 is made free, e.g. forming a free part with a height of 10-20 nm. The etching may be done on time base using the known etching rate.

Subsequently (see FIG. 3) a 60 nm thick layer 3 of a conducting material like a metal is deposited over the structure. This is done using e.g. vapor deposition or sputtering as the deposition technique. The conducting layer 3 in this way also surrounds upper parts of the nano-wires 1 thus improving the rigidity of their attachment and of the structure. The deposition may be continued in such a way that all cavities in between two neighboring nano-wires 1 are completely removed, the latter not being shown in the drawing. The metal 3 can be selected to form a good ohmic contact to the semiconductor material of the nano-wire. If desired or needed, a heating step can be used to form or improve the contact, either at this stage if the fill material is thermally stable or at a latter stage if this is not the case.

Next (see FIG. 4) the layer 4 of the fill material is removed by means of selective etching. If for the fill material a resist is used, a commercially available remover may be used. For inorganic fill materials wet etching can also be used. Subsequently, the device 10 is provided with means for introducing a fluid 20 into the sensor device, the fluid 20 comprising substances or compounds to be detected by the sensor device 10. Such means are however not shown in the drawing. The device 10 may also be incorporated into a structure comprising such means or its manufacture may be integrated with the manufacturing of the device 10. The two contact regions 3,2 contacting the nano-wires 1 can be provided with contact wires 30 or with a pattern of conductors performing this function, which can be connected to a current measuring device, the latter not being shown in the drawing. Preferably, such current measuring device is a small circuit that may be formed in advance in the semiconductor body 11 using semiconductor technology.

After etching the fill material 4, a washing step is done using a low-surface tension liquid like an alcohol. Preferably however, the structure is dried using supercritical CO2 drying. This can be done e.g. by an apparatus like Bal-Tec CPD Critical Point Dryer.

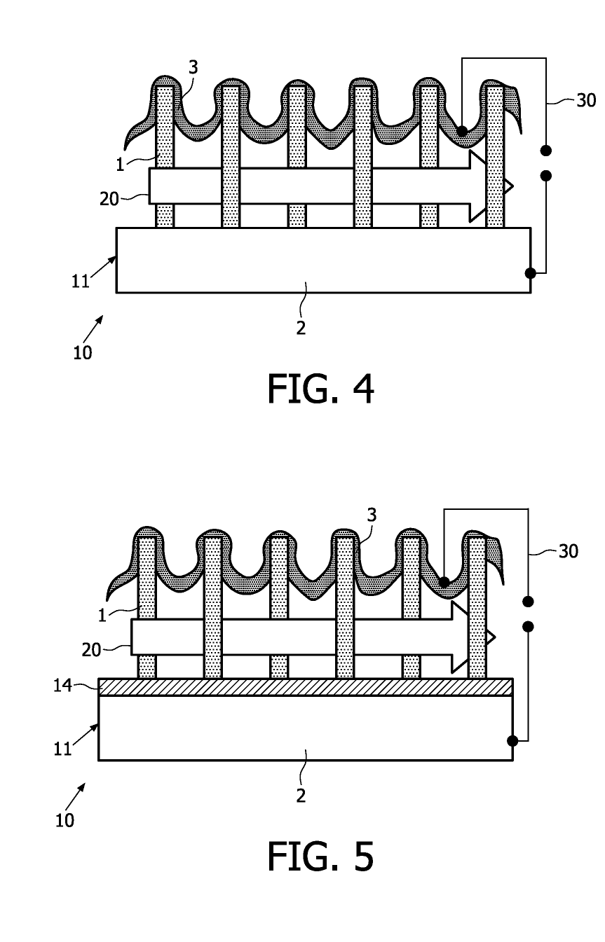

FIG. 5 is a sectional view of another semiconductor sensor device at a relevant stage in its manufacture by means of another method in accordance with the invention. The construction of the sensor and is manufacturing is largely the same as described above in the first example to which here is referred. The difference is formed by the presence of an insulating layer 14 on top of the semiconductor substrate 2 and between the feet of neighboring nano-wires 1. Such a layer 14 may comprise silicon dioxide and may be deposited as indicated above for such a material. On top thereof the (further) fill material comprising e.g. a resist is again deposited by spin coating as in the previous example. Such a resist may easily be removed selectively also with respect to the insulating layer 14. Layer 14 not only forms a more solid attachment of the nano-wires 1 to the substrate 2 but also prevents a short circuit between the upper and lower contacts 2,3 in case of an electrically conducting fluid, in particular an electrically conducting liquid, 20 carrying the substance/compound to be detected.

It will be obvious that the invention is not limited to the examples described herein, and that within the scope of the invention many variations and modifications are possible to those skilled in the art.

For example it is to be noted that the invention is not only suitable for the manufacture of a sensor comprising a large number of nano-wires but also a small number of such wires up to even one single nano-wire is feasible selection. Each nano wire region can for part of a single (part of a) device but it also is possible to use a plurality of nano wires forming a part of a single device or of a single region of a device. Thus, e.g. conducting semiconducting layers (for example of the n-type) may be uniformly formed before formation of the semiconducting nano-wires and thereinafter. In this way, a doping step during growth of the nano-wires may be avoided if desired.

Furthermore it is noted that various modifications are possible with respect to individual steps. For example other deposition techniques can be selected instead of those used in the example. The same holds for the materials selected. Thus, the (further) fill material be made of e.g. silicon nitride or of other dielectrics.

1. Method of manufacturing a semiconductor sensor device (10) for sensing a substance comprising a plurality of mutually parallel mesa-shaped semiconductor regions (1) which are formed on a surface of a semiconductor body (11) and which are connected at a first end to a first electrically conducting connection region (2) and at a second end to a second electrically conducting connection region (3) while a fluid comprising a substance to be sensed can flow between the mesa-shaped semiconductor regions (1) and the substance to be sensed can influence the electrical properties of the plurality of the mesa-shaped semiconductor regions (1), wherein at the surface of the semiconductor body (11) the first connection region (2) is formed and connected thereto with the first end the plurality of mesa-shaped semiconductor regions (1) is formed, and subsequently the second connection region (3) is formed connected to the plurality of mesa-shaped semiconductor regions (1) at their second end, characterized in that after formation of the plurality of mesa-shaped semiconductor regions (1) the free space between these regions (1) is filled with a fill material (4) that can be selectively removed with respect to the material of the plurality of mesa-shaped semiconductor regions (1) and other bordering parts of the semiconductor sensor device (10), subsequently a conducting layer (30) is deposited over the resulting structure from which the second connection region (3) is formed whereinafter the fill material (4) is removed in a selective manner by which the space between the plurality of mesa-shaped semiconductor regions (1) is made free again.

2. Method according to claim 1, characterized in that before the conducting layer (30) is deposited, an upper part (4A) of the fill material (4) is removed by selective etching by which an upper part of the plurality of mesa-shaped semiconducting regions (1) is made free.

3. Method according to claim 2, characterized in that the fill material (4) is removed almost completely and the space between the plurality of mesa-shaped semiconductor regions (1) is filled with a further fill material different from the fill material.

4. Method according to claim 3, characterized in that before the conducting layer (30) is deposited, an upper part of the further fill material is removed by etching by which an upper part of the plurality of mesa-shaped semiconductor regions (1) is made free.

5. Method according to claim 1, characterized in that for the material (4) of the fill material or the further fill material an insulating material is selected.

6. Method according to claim 1, characterized in that for the material of the fill material (4) or the further fill material a polymer is used which is deposited by spin coating.

7. Method according to claim 1, characterized in that the material of the fill material (4) or the further fill material is selectively etched by wet etching.

8. Method according claim 7, characterized in that after etching of fill material (4) or the further fill material, the capillary forces in the space between the plurality of mesa-shaped semiconducting regions (1) in a subsequent drying step are reduced.

9. Method according to claim 8, characterized in that the capillary forces during drying are reduced by introducing between the etching and drying step a washing step using a liquid with a low surface tension.

10. Method according to claim 8, characterized in that the capillary forces during drying are reduced by using supercritical cabondioxide drying.

11. Method according to claim 1, characterized in that the material of the fill material (4) or the further fill material an organic substance is used which is selectively removed by dry etching using oxygen or another reactive component.

12. Method according to claim 1, characterized in that for the material of the fill material (4) or the further fill material an organic substance is used and said (further) fill material (4) is removed in a selective manner by a thermal treatment.

13. Method according to claim 1, characterized in that after formation of the plurality of mesa-shaped semiconductor regions (1) the free space between these regions (1) is filled with a fill material (4) by means of completely burying said regions (1) with a layer of the fill material (4) followed by a chemical-mechanical polishing step by which the upper surface of said regions (1) is made free.

14. Method according to claim 1, characterized in that for the plurality of mesa-shaped semiconductor regions (1) a nano-wire (1) is chosen.

15. Method according to claim 1, characterized in that for the plurality of mesa-shaped semiconductor regions (1) a nano-wire (1) is chosen.

16. Method according to claim 1, characterized in that the mesa-shaped semiconductor regions are formed as a normally off element or as a part of an active element such as a transistor of the normally off type.

17. Semiconductor sensor device (10) for sensing a substance comprising a plurality of mutually parallel mesa-shaped semiconductor regions (1) which are formed on a surface of a semiconductor body (11) and which are connected at a first end to a first electrically conducting connection region (2) and at a second end to a second electrically conducting connection region (3) while a fluid comprising a substance to be sensed can flow between the mesa-shaped semiconductor regions (1) and the substance to be sensed can influence the electrical properties of the plurality of the mesa-shaped semiconductor regions (1), wherein at the surface of the semiconductor body (11) the first connection region (2) is formed and connected thereto with the first end the plurality of mesa-shaped semiconductor regions (1) is formed, and the second connection region (3) is formed connected to the plurality of mesa-shaped semiconductor regions (1) at their second end and to part of the sidewalls of the plurality of mesa-shaped semiconductor regions (1).
